(19) United States
(12) Patent Application Publication
(10) Pub. No.: US 2024/0266169 A1
(43) Pub. Date: Aug. 8, 2024

(54) POWER SEMICONDUCTOR DEVICE MANUFACTURING METHOD

(71) Applicant: JUSUNG ENGINEERING CO., LTD., Gwangju-Si, Gyeonggi-Do (KR)

(72) Inventor: Chul Joo HWANG, Gwangju-Si, Gyeonggi-Do (KR)

(21) Appl. No.: 18/568,801

(22) PCT Filed: Jun. 10, 2022
(86) PCT No.: PCT/KR2022/008225

§ 371 Date: Dec. 8, 2023

(30) Foreign Application Priority Data
Jun. 11, 2021 (KR) 10-2021-0076036
Jun. 9, 2022 (KR) 10-2022-0070240

(51) Int. Cl. H01L 21/02; H01L 29/66

(52) U.S. Cl. CPC H01L 21/0262; H01L 21/02378; H01L 21/02458; H01L 21/02664; H01L 29/66522

(57) ABSTRACT

Provided is a method for manufacturing a power semiconductor device, which includes forming an active layer on an SiC substrate. The forming of the active layer includes injecting a source gas onto the SiC substrate, performing primary purging of injecting a purge gas after stopping the injecting of the source gas, injecting a reactant gas after stopping the primary purging, and performing secondary purging of injecting the purging gas after stopping the injecting of the reactant gas. Thus, in accordance with exemplary embodiments, the active layer may be formed at a low temperature. Therefore, a substrate or a thin film formed on the substrate may be prevented from being damaged by high-temperature heat. In addition, power or a time required for heating the substrate to form the active layer may be saved, and an overall process time may be shortened.

### TECHNICAL FIELD

The present disclosure relates to a method for manufacturing a power semiconductor device, and more particularly, to a method for manufacturing a power semiconductor device, in which an active layer is formed through an atomic layer deposition method.

### BACKGROUND ART

A field effect transistor includes an active layer formed on a substrate, source and drain electrodes formed above the active layer, a gate electrode formed to be disposed between the source electrode and the drain electrode above the active layer, and a well region provided between the source electrode, the drain electrode, and the active layer.

The active layer is formed by a metal organic chemical vapor deposition (MOCVD) method. Here, a thin film is deposited to deposit the active layer in a state in which the substrate is adjusted to a high temperature of approximately 1,200° C. That is, when the substrate is maintained at a high temperature of approximately 1,200° C., the active layer may be deposited on the substrate.

However, as the active layer is formed while the substrate is heated to the high-temperature, there is a limitation in that the substrate or the thin film formed on the substrate is damaged. In addition, this acts as a factor that deteriorates a function of the field effect transistor or causes a defect. Particularly, when the field effect transistor is used for power conversion or control of an electronic device, the damage caused when the active layer is formed at the high temperature becomes a factor that significantly degrades quality or function.

### DISCLOSURE OF THE INVENTIVE CONCEPT

### Technical Problem

The present disclosure provides a method for manufacturing a power semiconductor device that is capable of being manufactured at a low temperature.

The present disclosure also provides a method for manufacturing a power semiconductor device that is capable of forming an active layer at a low temperature.

### Technical Solution

In accordance with an exemplary embodiment, a method for manufacturing a power semiconductor device, which includes forming an active layer on an SiC substrate, wherein the forming of the active layer includes: injecting a source gas onto the SiC substrate; performing primary purging of injecting a purge gas after stopping the injecting of the source gas; injecting a reactant gas after stopping the primary purging; and performing secondary purging of injecting the purging gas after stopping the injecting of the reactant gas.

The source gas may include one or two or more of Ga, In, Zn, and Si.

The reactant gas may include one or two or more of As, P, 0, and C.

The forming of the active layer may include repeatedly performing one process cycle, in which the injecting of the source gas, performing of the primary purging, the injecting of the reactant gas, and the performing of the secondary purging are sequentially performed.

The forming of the active layer may include generating plasma after the injecting of the reactant gas.

The generating of the plasma after the injecting of the reactant gas may be performed after the performing of the secondary purging, and the forming of the active layer may include repeatedly performing one process cycle, in which the injecting of the source gas, the performing of the primary purging, the injecting of the reactant gas, the performing of the secondary purging, and the generating of the plasma are sequentially performed.

The forming of the active layer may include generating plasma between the injecting of the source gas and the injecting of the reactant gas.

The generating of the plasma may include injecting a hydrogen gas.

The method may further include, before the forming of the active layer, forming a crystalline buffer layer on the SiC substrate.

The buffer layer may be made of AlN.

The method may further include forming a well region in the active layer after the forming of the active layer, wherein the forming of the well region may include: exposing a partial area of the active layer in which the well region is formed; etching the exposed partial area of the active layer; and sequentially the injecting of the source gas, the injecting of the purge gas, the injecting of the reactant gas, and the injecting of the purge gas to form the well region in the exposed area of the active layer.

At least one of the forming of the active layer or the forming of the well region may include injecting a doping gas, wherein the doping gas may be injected after the doping gas is mixed with the source gas and is injected or after the source gas is injected.

The doping gas may include one of Mg, Si, In, Al, and Zn.

The method may further include: forming a gate insulating layer on the active layer; forming a source electrode and a drain electrode on the well region so that the source electrode and the drain electrode are spaced apart from each other in a horizontal direction; and forming a gate electrode on the gate insulating layer.

### Advantageous Effects

In accordance with the exemplary embodiments, the active layer may be formed at the low temperature. Thus, the substrate or the thin film formed on the substrate may be prevented from being damaged by the high-temperature heat. In addition, the power or time required for heating the substrate to form the active layer may be saved, and the overall process time may be shortened.

In addition, the active layer may be crystallized to be formed. That is, the crystallized active layer may be formed while forming the active layer at the low temperature.

### BRIEF DESCRIPTION OF THE DRAWINGS

FIG. 1 is a conceptual view illustrating a substrate on which an active layer is formed through a method in accordance with an exemplary embodiment;

FIG. 2 is a cross-sectional view illustrating an example of a field effect transistor manufactured through the method in accordance with an exemplary embodiment;

FIG. 3 is a conceptual view for explaining a method for forming the active layer of the field effect transistor through the method in accordance with an exemplary embodiment;

FIG. 4 is a conceptual view illustrating a modified example in which a buffer layer is disposed between the active layer and the substrate;

FIG. 5 is a view illustrating an example of a field effect transistor in accordance with a modified example of the exemplary embodiment;

FIG. 6 is a schematic view illustrating a deposition device used in a method for manufacturing a power semiconductor device in accordance with an exemplary embodiment; and

FIG. 7 is a schematic view illustrating another example of the deposition device used in the method for manufacturing the power semiconductor device in accordance with an exemplary embodiment.

### MODE FOR CARRYING OUT THE INVENTIVE CONCEPT

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the figures, the dimensions of layers and regions are exaggerated for clarity of illustration. Like reference numerals refer to like elements throughout.

An exemplary embodiment of the present disclosure relates to a method for manufacturing a power semiconductor device. In more detail, an exemplary embodiment of the present disclosure relates to a method for manufacturing a power semiconductor device, which includes a method for forming an active layer through an atomic layer deposition (ALD) method.

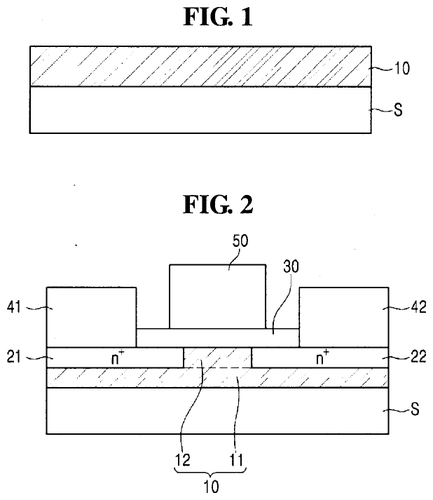

FIG. 1 is a conceptual view illustrating a substrate on which an active layer is formed through a method in accordance with an exemplary embodiment.

Referring to FIG. 1, an active layer 10 is a layer disposed on a substrate S and may be a layer constituting a power semiconductor device, more specifically, a field effect transistor. The active layer 10 may be formed through the atomic layer deposition (ALD) method. In addition, in the forming of the active layer 10 through the atomic layer deposition method, the active layer may be formed by generating plasma after stopping or finishing an injection of a reactant gas. Here, the active layer 10 may be formed by generating plasma using a hydrogen (H₂) gas (hereinafter, referred to as hydrogen plasma).

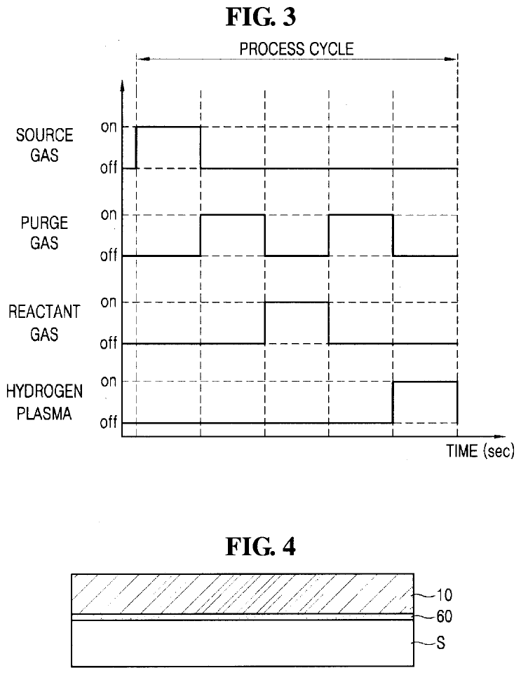

FIG. 2 is a cross-sectional view illustrating an example of the field effect transistor manufactured through the method in accordance with an exemplary embodiment. FIG. 3 is a conceptual view for explaining a method for forming the active layer of the field effect transistor through the method in accordance with an exemplary embodiment.

Hereinafter, a method of manufacturing the power semiconductor device including the active layer formed by the method in accordance with an exemplary embodiment will be described with reference to FIGS. 1 to 3. Here, the field effect transistor, which is one of the power semiconductor devices, will be described as an example.

Referring to FIG. 2, the field effect transistor manufactured through the method in an exemplary embodiment may include a substrate S, an active layer 10 disposed on the substrate S, source and drain electrodes 41 and 42 disposed above the active layer 10 so as to be spaced apart from each other in a horizontal direction, a gate electrode 50 disposed above the active layer 10 so as to be disposed between the source electrode 41 and the drain electrode 42, well layers 21 and 22 respectively disposed between the source electrode 41 and the active layer 10 and between the drain electrode 42 and the active layer 10, and a gate insulating layer 30 disposed between the active layer 10, the well layers 21 and 22, and the gate electrode 50 so as to be disposed between the source electrode 41 and the drain electrode 42.

Here, the well layer 21 disposed to be in contact with the source electrode 41 or below the source electrode 41 may be a layer functioning as a source of the field effect transistor. In addition, the well layer 22 disposed to be in contact with the drain electrode 42 or below the drain electrode 42 may be a layer functioning as a drain of the field effect transistor.

The substrate S may be a substrate including silicon (Si) or a p-type substrate. More specifically, the substrate S may be a p-type SiC substrate.

The active layer 10 may be a layer or thin film made of any one of gallium arsenic (GaAs), indium phosphide (InP), aluminum gallium indium phosphide (AlGaInP), indium gallium zinc oxide (IGZO), indium zinc oxide (IZO), and silicon carbide (SiC). That is, the active layer 10 may be provided as any one of a GaAs layer, an InP layer, an AlGaInP layer, an IGZO layer, an IZO layer, and a SiC layer.

In addition, the active layer 10 may be formed through the atomic layer deposition (ALD) method. In addition, in the forming of the active layer 10 through the atomic layer deposition method, the active layer may be formed by generating plasma after stopping or finishing an injection of an reactant gas. Here, the active layer 10 may be formed by generating plasma using a hydrogen (H₂) gas (hereinafter, referred to as hydrogen plasma).

When the method for forming the active layer 10 using the atomic layer deposition method is described in more detail with reference to FIG. 3, a process of forming the active layer 10 may include a process of injecting a source gas, a process (primary purging) of injecting a purge gas, a process of injecting a reactant gas, and a process (secondary purging) of injecting the purge gas. In addition, the process of forming the active layer 10 may include a process of generating plasma after the process of injecting the reactant gas. Here, the process of generating the plasma may be performed, for example, after the reactant gas is injected, and the secondary purging is finished. In this case, the injection of the source gas, the injection of the purge gas (primary purge), the injection of the reactant gas, the injection of the purge gas (secondary purging), and the generation of the plasma may be performed sequentially. In addition, the plasma generated after the secondary purging may be hydrogen plasma. That is, in the generation of the plasma after finishing the secondary purging, the plasma may be generated by injecting a hydrogen gas and discharging the hydrogen gas.

In addition, the plasma may be generated in the process of injecting the reactant gas. That is, the plasma may be generated by injecting the reactant gas and discharging the reactant gas.

In the forming of the active layer 10, ‘the injection of the source gas-the injection of the purge gas (primary purge)-the injection of the reactant gas-the injection of the purge gas (secondary purging)-the generation of the plasma’ as described above to form the active layer 10 may be defined as one process cycle. In addition, the above-described process cycle may be performed several times to perform the deposition of the atomic layer several times. In addition, the number of times of the process cycle to be performed may be adjusted to form the active layer 10 having a target thickness.

In the process cycle as described above, when the reactant gas is injected after the injection of the source gas and the injection of the purge gas injection (primary purging), reaction between the source gas and the reactant gas occurs on the substrate S to generate a reactant, for example, AlGaInP. Then, the reactant is accumulated or deposited on the substrate S to form a thin film made of AlGaInP on the substrate S.

In the related art, in the deposition of the thin film to form the active layer on the substrate, the inside of the chamber or the substrate may be maintained at a high temperature of approximately 1,200° C. In other words, the thin film may be deposited on a top surface of the substrate only when the inside of the chamber or the substrate is maintained at the high temperature of approximately 1,200° C. When the active layer is formed at the high temperature, the substrate or the thin film formed on the substrate may be damaged, and the active layer may be damaged. Thus, there is a limitation in that a function or quality of the device is deteriorated.

However, in an exemplary embodiment, the plasma is generated in the depositing of the thin film using the atomic layer deposition method. That is, the plasma, for example, the hydrogen plasma is generated after the reactant gas is injected or after the injection of the reactant gas is finished. More specifically, after the reactant gas injection, and the injection of the purge gas (secondary purging) are finished, the plasma using the hydrogen gas is generated.

Here, the plasma may improve a reaction rate between the source gas and the reactant gas and may allow the reactant between the source gas and the reactant gas to be easily deposited or attached to the substrate S. Thus, the active layer 10 may be formed by the atomic layer deposition method in a state in which the inside of the chamber 100 or the substrate S has a low temperature of, for example, approximately 600° C. or less. In more detail, the active layer 10 may be formed by the atomic layer deposition method at a temperature of approximately 300° C. or more to approximately 550° C. or less. That is, the active layer 10 may be formed at a low temperature without forming the active layer 10 in a state in which the substrate is heated to a high temperature as in the related art. Thus, the substrate S, for example, the thin film or the active layer 10 formed on the substrate due to high heat may be prevented from being damaged.

In addition, the plasma may allow the thin film deposited on the substrate S to become crystalline by the reaction between the source gas and the reactant gas. More specifically, the polycrystalline active layer 10 may be formed. That is, in the forming of the active layer 10 by the atomic layer deposition method, the plasma may be generated after injecting the reactant gas, and thus, the crystalline or polycrystalline active layer 10 may be formed by the plasma.

In addition, the plasma may decompose impurities remaining in the chamber 100 to facilitate removal. Thus, contamination due to the impurities when the deposition film, that is, the active layer 10 is formed may be prevented or suppressed.

In the above, it has been described that the plasma is generated after the finishing of the secondary purging or after injecting the reactant gas. However, an exemplary embodiment of the present disclosure is not limited thereto, and the hydrogen plasma may be generated in a process between the injection of the source gas and the injection of the reactant gas. More specifically, the hydrogen plasma may be generated between the process of injecting the source gas and the primary purging process. That is, ‘the injection of the source gas-the generation of the plasma-the injection of the purge gas (primary purging)-the injection of the reactant gas-the injection of the purge gas (secondary purging)’ may be used as one process cycle.

As another example, the hydrogen plasma may be generated between the primary purging process and the reactant gas injection process. Thus, ‘the injection of the source gas-the injection of the purge gas (primary purging)-the generation of the plasma-the injection of the reactant gas-the injection of the purge gas (secondary purging)’ may be defined as one process cycle.

As another example, the plasma may be generated in each of the process between the injection of the source gas and the injection of the reactant gas and after the process of injecting the reactant gas. That is, ‘the injection of the source gas-the generation of the plasma-the injection of the purge gas (primary purging)-the injection of the reactant gas-the injection of the purge gas (secondary purging)-the generation of the plasma’ may be defined as the process cycle, or ‘the injection of the source gas-the injection of the purge gas (primary purging)-the generation of the plasma-the injection of the reactant gas-the injection of the purge gas (secondary purging)-the generation of the plasma’ may be defined as the process cycle.

In the forming of the active layer 10 in the process cycle as described above, materials of the source gas and the reactant gas may be determined according to the type of the active layer 10 to be formed.

The active layer 10 may be made of any one of a GaAs layer, an InP layer, an AlGaInP layer, an IGZO layer, an IZO layer, and a SiC layer. In this case, the source gas may be a gas including any one or two or more of Ga, In, Zn, and Si. That is, the source gas may be a gas including any one or two or more of a gas containing Ga, a gas containing In, a gas containing Al, Ga, and In (a gas containing AlGaIn), a gas containing In, Ga, and Zn (a gas containing IGZ), a gas containing In and Zn (a gas containing IZ), and a gas containing Si. In addition, the reactant gas may be a gas including any one or two or more of As, P, O, and C. That is, the reactant gas may be a gas including any one or two or more of an As-containing gas, a P-containing gas, an O-containing gas, and a C-containing gas.

For example, when a GaAs layer is formed as the active layer 10, the gas containing Ga may be used as the source gas, and the gas containing As may be used as the reactant gas. In addition, when the InP layer is formed as the active layer 10, the gas containing In may be used as the source gas, and the gas containing P may be used as the reactant gas. As another example, when forming the AlGaInP layer as the active layer 10, the gas containing Al, the gas containing Ga, or the gas containing In may be used as the source gas, and the gas containing P may be used as the reactant gas. As another example, when forming the IGZO layer as the active layer 10, the gas containing In, the gas containing Ga, and the gas containing Zn may be used as the source gas, and the gas containing O may be used as the reactant gas. In addition, when the IZO layer is formed as the active layer 10, the gas containing In or the gas containing Zn may be used as the source gas, and the gas containing O may be used as the reactant gas. In addition, when the SiC layer is formed as the active layer 10, the gas containing Si may be used as the source gas, and the gas containing C may be used as the reactant gas.

Here, a gas containing trimethyl gallium (Ga(CH₃)₃) (TMGa) may be used as, for example, the Ga-containing gas, and a gas containing at least one of trimethyl indium (In(CH₃)₃) (TMIn) or diethylamino propyl dimethyl indium (DADI) may be used as, for example, the In-containing gas. In addition, a gas containing trimethylaluminum (A(CH₃)₃) (TMA) may be used as, for example, the Al-containing gas, and a gas containing at least one of diethyl zinc (Zn(C₂H₅)₂) (DEZ) or dimethyl zinc (Zn(CH₃)₂)) (DEZ) may be used as the Zn-containing gas. In addition, a gas containing at least one of SiH₄ and Si₂H₆ may be used as, for example, the Si-containing gas.

In addition, a gas containing any one of AsH₃ and AsH₄ may be used as the As-containing gas, and a gas containing, for example, phosphine (PH₃) may be used as the P-containing gas. In addition, the O-containing gas may be oxygen, and the C-containing gas may be, for example, a gas containing SiH₃CH₃.

As described above, when forming the active layer 10 of the GaAs layer, the Ga-containing gas is used as the source gas, and when forming the active layer 10 of the InP layer, the In-containing gas is used as the source gas. In addition, when forming the active layer 10 of the SiC layer, the Si-containing gas is used as the source gas. Thus, when the active layer 10 is made of any one of a GaAs layer, an InP layer, and a SiC layer, the active layer 10 may be described as using one type of source gas.

As another example, when the active layer 10 of the AlGaInP layer is formed, three kinds of gases, i.e., the Al-containing gas, the Ga-containing gas, and the In-containing gas are used as the source gas. As another example, when the active layer 10 is formed with the IGZO layer, three kinds of gases, i.e., the In-containing gas, the Ga-containing gas, and the Zn-containing gas are used as the source gas. Thus, when the active layer 10 is formed as the AlGaInP layer or the IGZO layer, it may be described as using two or more kinds, i.e., a plurality of source gases.

In the forming of the active layer 10 by using or injecting the plurality of source gases, the active layer 10 may be formed by injecting the plurality of source gases mixed with the source gases. A detailed description of a method for mixing and injecting the plurality of source gases will be described later when the deposition device is described.

Also, in the forming of the active layer 10, a doped active layer may be formed by injecting a doping gas. In this case, the doping gas may be a gas including any one of Mg, Si, In, Al, and Zn. As a more specific example, a gas containing polysilane (H₃Si—(SiH₂)ₙ—SiH₃) may be used as the doping gas containing Si. As another example, a gas containing Cp2Mg may be used as the doping gas containing Mg. In addition, the second doping gas may be one or a mixture of one or more of Si, In, Al, and Zn.

In addition, the doping gas may be mixed with the source gas and then injected together. Of course, the source gas and the doping gas may be injected to be divided into separate processes. That is, the active layer 10 may be formed by using ‘the injection of the source gas-the injection of the doping gas-the injection of the purge gas (primary purging)-the injection of the reactant gas-the injection of the purge gas (secondary purging)-the generation of the plasma’ as the process cycle.

Then, the above-described process cycle is repeated a plurality of times to form the active layer 10. Here, in the process cycle performed initially or primarily to form the active layer 10, the process cycle may be performed without the process of injecting the doping gas. That is, the process cycle performed primarily to form the active layer 10 may be a process cycle of ‘the injection of the source gas-the injection of the purge gas (primary purging)-the injection of the reactant gas-the injection of the purge gas (secondary purging)-the generation of the plasma’. Here, the doping gas may be injected together when the source gas is injected, or the doping gas may not be separately injected. Also, the doping gas may be injected together when the source gas is injected from the subsequent process, or the doping gas may be injected after injecting the source gas. Thus, when the active layer 10 is formed on the active layer 10, the thin film deposited by the primary process cycle is an undoped thin film, and the thin film deposited by the subsequent process cycle may be a doped thin film.

The active layer 10 may be provided in a stepped shape so that heights of the surface are different from each other as illustrated in FIG. 2. In other words, the active layer 10 may be described as including a first layer 11 formed on the top surface of the substrate S and a second layer 12 formed on a partial area of the first layer 11. Thus, a thickness of a region of the active layer 10, in which the second layer 12 is formed, may be thicker than those of other regions. In other words, the active layer 10 may be provided in a shape in which a height of an area, on which the second layer 12 is formed, is greater than that of a portion, at which only the first layer 11 is formed, that is, in a shape having a height difference.

The shape of the active layer 10 is not limited to be provided in the stepped shape as described above, and if well layers 21 and 22 are provided between the source electrode 41 and the active layer 10 and between the drain electrode 42 and the active layer 10, respectively, the active layer 10 may be provided in any shape.

The well layers 21 and 22 may be layers commonly referred to as well regions in the field effect transistor. Here, since the well regions are formed in the active layer by being deposited through the atomic layer deposition method, the well regions will be referred to as the well layers 21 and 22 for convenience of description. The well layers 21 and 22 may be provided to be disposed between the source and drain electrodes 41 and 42 and the active layer 10. Thus, the well layers 21 and 22 are provided to be disposed between the first layer 11 of the active layer 10 and the source electrode 41 and between the first layer 11 and the drain electrode 42 as illustrated in FIG. 2.

The well layers 21 and 22 may be provided so that n-type or p-type impurities are doped into the same material as the active layer 10. For example, when the active layer 10 is made of AlGaInP, the well layers 21 and 22 may be formed in an n-type by doping an impurity such as Si into AlGaInP. In addition, the doping gas may be provided to the n-type well layers 21 and 22 by mixing one or more gases of In, Al, and Zn. Thus, the well layers 21 and 22 may be described as n-type AlGaInP layers doped with Si.

The well layers 21 and 22 may be formed through the atomic layer deposition method. That is, the well layers 21 and 22 may be formed by using ‘the injection of the source gas-the injection of the purge gas (primary purging)-the injection of the reactant gas-the injection of the purge gas (secondary purging)’ as the process cycle. In this case, the source gas, the reactant gas, and the purge gas, which are injected to form the well layers 21 and 22, may be the same as the gas used to form the active layer 10. In addition, the doping gas may be injected together in the process of injecting the source gas. That is, the source gas and the doping gas may be mixed, and the mixed gas may be injected.

Of course, the source gas and the doping gas may be injected to be divided into separate processes. That is, after the source gas is injected, the doping gas may be injected. Thus, the well layers 21 and 22 may be formed by using ‘the injection of the source gas-the injection of the purge gas (primary purging)-the injection of the reactant gas-the injection of the purge gas (secondary purging)’ as the process cycle.

Then, the above-described process cycle is repeated a plurality of times to form the well layers 21 and 22. Here, in the process cycle performed initially or primarily to form the well layers 21 and 22, the process cycle may be performed without the process of injecting the doping gas. That is, the process cycle performed primarily to form the well layers 21 and 22 may be a process cycle of ‘the injection of the source gas-the injection of the purge gas (primary purging)-the injection of the reactant gas-the injection of the purge gas (secondary purging)’. Here, the doping gas may be injected together when the source gas is injected, or the doping gas may not be separately injected. Also, the doping gas may be injected together when the source gas is injected from the subsequent process, or the doping gas may be injected after injecting the source gas. Thus, when the well layers 21 and 22 are formed on the active layer 10, the thin film deposited by the primary process cycle is an undoped thin film, and the thin film deposited by the subsequent process cycle may be a doped thin film.

In addition, in the forming of the well layers 21 and 22, the plasma may be generated when the reactant gas is injected, or the plasma may be additionally generated after the secondary purging. Also, the plasma generated after the secondary purging may be a hydrogen plasma.

The well layers 21 and 22 formed as described above function as source and drain regions in the field effect transistor. That is, the well layer 21 formed below the source electrode 41 functions as a source of the field effect transistor, and the well layer 22 formed below the drain electrode 42 functions as a drain of the field effect transistor.

In the above description, it has been described that each of the well layers 21 and 22 provided below the source electrode 41 and the drain electrode 42 is provided in an n-type. However, an exemplary embodiment is not limited thereto, and each of the well layers 21 and 22 may be provided in a p-type according to the type of the field effect transistor to be manufactured.

The gate insulating layer 30 may be formed on the active layer 10. More specifically, the gate insulating layer 30 may be formed to be disposed between the gate electrode 50 and the active layer 10 in a vertical direction. Also, the gate insulating layer 30 may be formed to be disposed between the source electrode 41 and the drain electrode 42 in a width or length direction. The gate insulating layer 30 may be made of any one of SiO₂, SiON, and Al₂O₃. In addition, the gate insulating layer 30 may be formed through any one of a chemical vapor deposition (CVD) method, a metal organic chemical vapor deposition (MOCVD) method, and an atomic layer deposition (ALD) method.

The source and drain electrodes 41 and 42 may be formed on the well layers 21 and 22 so that the gate insulating layer 30 and the gate electrode 50 are disposed therebetween. That is, the source electrode 41 may be formed at one side of the gate insulating layer 30, and the drain electrode 42 may be formed at the other side of the gate insulating layer 30. In this case, each of the source and drain electrodes 41 and 42 may be made of a material including a metal, for example, may be made of at least one of Ti or Au. In addition, the source and drain electrodes 41 and 42 are formed through, for example, the chemical vapor deposition (CVD) method, the metal organic chemical vapor deposition (MOCVD) method, the atomic layer deposition (ALD) method, sputtering deposition method, or the like.

The gate electrode 50 may be formed on the gate insulating layer 30. In other words, the gate electrode 50 may be formed on the gate insulating layer 30 to be disposed between the source electrode 41 and the drain electrode 42. In this case, the gate electrode 50 may be made of a material including a metal, for example, may be made of a material including at least one of Ti or Au. Also, the gate electrode 50 may be formed through the sputtering deposition method.

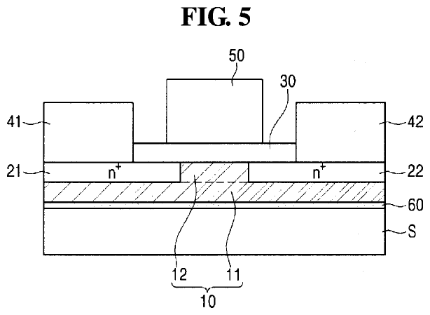

FIG. 4 is a conceptual view illustrating a modified example in which a buffer layer is disposed between the active layer and the substrate. FIG. 5 is a view illustrating an example of the field effect transistor in accordance with a modified example of the exemplary embodiment.

Referring to FIGS. 4 and 5, a buffer layer 60 may be formed between the substrate S and the active layer 10. In addition, as illustrated in FIG. 5, the field effect transistor according to the modified example may include a buffer layer 60 formed between the substrate S and the active layer 10. That is, the field effect transistor according to the modified example includes the buffer layer 60 formed between the substrate S and the active layer 10 when compared to the exemplary embodiment, and other configurations may be the same.

The buffer layer 60 may be a layer that is formed first on the substrate S before the active layer 10 is formed, i.e., may be a seed layer that assists the active layer 10 formed through the atomic layer deposition method to be more effectively crystallized. In other words, when the active layer 10 is formed through the atomic layer deposition method, the buffer layer 60 may be a seed layer that additionally assists in crystallization of the active layer 10 in addition to the crystallization by the hydrogen plasma. The buffer layer 60 may be made of AlN and may be formed through an atomic layer deposition method, the chemical vapor deposition method, or the like.

When the active layer 10 is deposited on the crystalline buffer layer 60 through the atomic layer deposition method, the active layer 10 may be grown in a crystal direction of the underlying buffer layer 60. Thus, the crystalline, more particularly, the polycrystalline active layer 10 may be more easily formed.

In the above description, the field effect transistor has been described as an example of the power semiconductor device. However, an exemplary embodiment is not limited thereto, and the manufacturing method in accordance with an exemplary embodiment is not limited to the field effect transistor and may be applied to manufacturing various power semiconductor devices including the active layer.

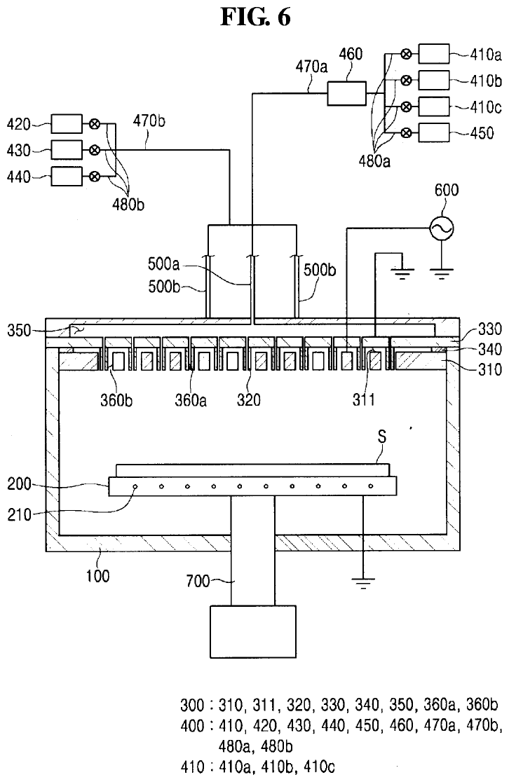

FIG. 6 is a schematic view illustrating a deposition device used in the method for manufacturing the power semiconductor device in accordance with an exemplary embodiment.

The deposition device may be a device for depositing a thin film through an atomic layer deposition (ALD) method. In this case, the deposition device may be a device for forming at least an active layer 10 among components of a power semiconductor device, for example, a field effect transistor. Also, the deposition device may be a device for forming the active layer 10 and well layers 21 and 22.

As illustrated in FIG. 6, the deposition device may include a chamber 100, a support 200 installed in the chamber 100 to support a substrate S, an injection part 300 disposed to face the support 200 and inject for injecting a gas for processes (hereinafter, referred to as a process gas) into the chamber 100, a gas supply part 400 configured to provide the process gas to the injection part 300, first and second gas supply tubes 500a and 500b connected to the injection part 300 so that the first and second gas supply tubes 500a and 500b have paths different from each other and configured to supply the gas provided from the gas supply part 400 to the injection part 300, and an RF power supply part 600 configured to apply power so that plasma is generated in the chamber 100.

In addition, the deposition device may further include a driving part 700 configured to operate the support 200 in at least one of elevating and rotating operations and an exhaust part (not shown) installed to be connected to the chamber 100.

The chamber 100 may include an inner space in which a thin film is disposed on the substrate S loaded into the chamber 100. For example, a cross-section thereof may have a shape such as a quadrangular shape, a pentagonal shape, or a hexagonal shape. Of course, a shape of the inside of the chamber 100 may be changed in various manners, the shape of the inside of the chamber 100 may be provided to correspond to that of the substrate S.

The support 200 is installed inside the chamber 100 to face the injection part 300 and supports the substrate S loaded into the chamber 100. A heater 210 may be provided inside the support 200. Thus, when the heater 210 is operated, the substrate S seated on the support 200 and the inside of the chamber 100 may be heated.

In addition, a separate heater may be provided inside the chamber 100 or outside the chamber 100 in addition to the heater 210 provided in the support 200 as a means configured to heat the substrate S or the inside of the chamber 100.

The injection part 300 may include a first plate 310 having a plurality of holes (hereinafter, referred to as holes 311) arranged in an extension direction of the support 200 and defined to be spaced apart from each other and disposed to face the support 200 inside the chamber 100, a nozzle 320 provided so that at least a portion thereof is inserted into each of the plurality of holes 311, and a second plate 330 installed to be disposed between an upper wall inside the chamber 100 and the first plate 310 inside the chamber 100.

In addition, the injection part 300 may further include an insulating part 340 disposed between the first plate 310 and the second plate 330.

Here, the first plate 310 may be connected to the RF power supply part 600, and the second plate 330 may be grounded. In addition, the insulating part 340 may serve to prevent electrical connection between the first plate 310 and the second plate 330.

The first plate 310 may have a plate shape extending in the extension direction of the support 200. In addition, the plurality of holes 311 are provided in the first plate 310, and each of the plurality of holes 311 may be provided to pass through the first plate 310 in a vertical direction. In addition, the plurality of holes 311 may be arranged in the extension direction of the first plate 310 or the support 200.

Each of the plurality of nozzles 320 may have a shape extending in the vertical direction, have a path through which a gas passes is provided therein, and have opened upper and lower ends. In addition, each of the plurality of nozzles 320 may be installed so that at least a lower portion thereof is inserted into the hole 311 provided in the first plate 310, and an upper portion thereof is connected to the second plate 330. Thus, the nozzle 320 may be described as a shape protruding downward from the second plate 330.

An outer diameter of the nozzle 320 may be provided to be less than an inner diameter of the hole 311. In addition, when the nozzle 320 is installed to be inserted into the hole 311, an outer circumferential surface of the nozzle 320 may be installed to be spaced apart from a peripheral wall of the hole 311 (i.e., an inner wall of the first plate 310). Thus, the inside of the hole 311 may be divided into an outer space of the nozzle 320 and an inner space of the nozzle 320.

In the inner space of the hole 311, the path in the nozzle 320 is a path through which the gas provided from the first gas supply tube 500a moves and is injected. In addition, in the inner space of the hole 311, the outer space of the nozzle 320 is a path through which the gas provided from the second gas supply tube 500b moves and is injected. Thus, hereinafter, the path within the nozzle 320 is referred to as a first path 360a, and the space outside the nozzle 320 within the hole 311 is referred to as a second path 360b.

The second plate 330 may be installed so that a top surface thereof is spaced apart from the upper wall of the chamber 100, and a bottom surface thereof is spaced apart from the first plate 310. Thus, empty spaces may be provided between the second plate 330 and the first plate 310 and between the second plate 330 and the upper wall of the chamber 100, respectively.

Here, an upper space of the second plate 330 may be a space (hereinafter, a diffusion space 350) in which the gas provided from the first gas supply tube 500a is diffused to move and may communicate with an upper opening of each of the plurality of nozzles 320. In other words, the diffusion space 350 is a space communicating with the plurality of first paths 360a. Thus, the gas passing through the first gas supply tube 500a may be diffused in the extension direction of the second plate 330 in the diffusion space 350 and then may pass through the plurality of first paths 360a and be injected downward.

In addition, a gun drill (not shown), which is a path through which gas moves, may be provided inside the second plate 330, and the gun drill may be connected to the second gas supply tube 500b and provided to communicate with the second path 360b. Thus, the gas provided from the second gas supply tube 500b may be injected toward the substrate S through the gun drill of the second plate 330 and the second path 360b.

The gas supply part 400 provides a gas that is necessary for depositing a thin film by an atomic layer deposition method. The gas supply part 400 may include a source gas storage part 410 in which a source gas is stored, a reactant gas storage part 420 in which a reactant gas reacting with the source gas is stored, a purge gas storage part 430 in which a purge gas is stored, a first transfer tube 470a installed to connect the source gas storage part 410 to the first gas supply tube 500a, and a second transfer tube 470b installed to connect the reactant gas storage part 420 and the purge gas storage part 430 to the second gas supply tube 500b.

Here, the purge gas stored in the purge gas storage part 430 may be, for example, an N2 gas or an Ar gas.

In addition, the gas supply part 400 may include a gas storage part for generating plasma, in which the gas supplied in a process of generating plasma inside the chamber 100 (hereinafter, referred to as plasma generating gas) is stored after the reactant gas is injected or after the secondary purging 440. Here, the gas for generating the plasma may be, for example, a hydrogen gas.

In addition, the gas supply part 400 may include a doping gas storage part 450, in which a doping gas is stored, and a mixing part 460 installed in the first transfer tube 470a to mix a plurality of types of gases.

Here, the gas stored in the doping gas storage part 450 may vary depending on a material to be doped. For example, a gas containing an n-type dopant material may be stored in the doping gas storage part 450 and may be, for example, a gas containing Si. In this case, a gas containing polysilane (H₃Si—(SiH₂)n-SiH₃) may be used as, for example, the Si-containing gas. As another example, a gas containing a p-type dopant material may be stored in the doping gas storage part 450 and may be, for example, a gas containing Mg. In this case, a gas containing Cp2Mg may be used as, for example, the Mg-containing gas. In addition, the doping gas may be one or a mixture of one or more of Si, In, Al, and Zn.

In addition, the gas supply part 400 may include a plurality of first connection tubes 480a connecting each of the source gas storage part 410 and the doping gas storage part 450 to the first transfer tube 470a, a valve installed in each of the plurality of first connection tubes 480a, a plurality of second connection tubes 480b connecting each of the reactant gas storage part 420, the purge gas storage part 430, and the gas storage part 440 for generating the plasma to the second transfer tube 470b, and a valve installed in each of the plurality of second connection tubes 480b.

The source gas storage part 410 may be provided in plurality, and different types of source gases may be stored in the plurality of source gas storage parts 410 (410a, 410b, and 410c), respectively. Also, the first connection tube 480a may be connected to each of the plurality of source gas storage parts 410a, 410b, and 410c, and the first connection tubes 480a respectively connected to the plurality of source gas storage parts 410a, 410b, and 410c may be connected to the first transfer tube 470a.

The mixing part 460 may be a means that mixes the gas provided from the plurality of source gas storage parts 410a, 410b, and 410c or mixes the gas provided from the source gas storage part 410 with the gas provided from the doping gas storage part 450. The mixing part 460 may be provided to have an inner space in which the gas is capable of being mixed. In addition, the mixing part 460 may be installed to connect the first connection tube 480a connected to each of the plurality of source gas storage parts 410a, 410b, and 410c and the doping gas storage part 450 to the first transfer tube 470a. Thus, the plurality of types of gases introduced into the mixing part 460 may be mixed in the mixing part 460 and then transferred to the first gas supply tube 500a through the first transfer tube 470a.

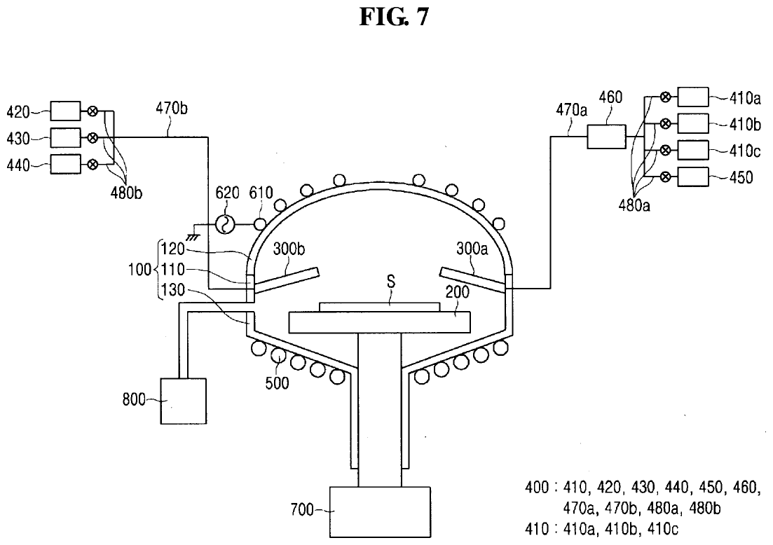

FIG. 7 is a schematic view illustrating another example of the deposition device used in the method for manufacturing the power semiconductor device in accordance with an exemplary embodiment.

A deposition device for forming an active layer 10 and well layers 21 and 22 of the power semiconductor device in accordance with an exemplary embodiment may not be limited to the device illustrated in FIG. 6, and the deposition device illustrated in FIG. 7 may be used.

Referring to FIG. 7, the deposition device may include a chamber 100, a support 200 installed in the chamber to support a substrate S, first and second gas injection parts 300a and 300b, each of which is installed in the chamber to face the support 200, a gas supply part 400 configured to supply a process gas to each of the first and second gas injection parts 300a and 300b, an antenna 610 provided with a coil for inducing electric fields in the chamber 100 to generate plasma, and a power supply part 620 connected to the antenna 610.

In addition, the deposition device may include a heating part 500 installed to face the support 200, a driving part 700 configured to elevate or rotate the support 200, and an exhaust part 800 configured to exhaust gases and impurities inside the chamber 100.

The chamber 100 may have a tubular shape having an inner space, in which a thin film is formed on the substrate S loaded into the chamber, for example, a dome shape as illustrated in FIG. 7. More specifically, the chamber 100 may include a chamber body 110, an upper body 120 installed on an upper portion of the chamber body 110, and a lower body 130 installed on a lower portion of the chamber body 110. The chamber body 110 may have a tubular shape having opened upper and lower portions, the upper body 120 may be installed to cover an upper opening of the chamber body 110, and the lower body 130 may be installed to cover a lower opening of the chamber body 110. In addition, the upper body 120 may have a dome shape having an inclined surface that increases in height toward a center in a width direction. In addition, the lower body 130 may have a dome shape having an inclined surface that decreases in height toward a center in a width direction. The chamber 100, that is, each of the chamber body 110, the upper body 120, and the lower body 130 may be made of a transparent material that allows light to pass therethrough and may be made of, for example, quartz.

The gas supply part 400 may be provided in the same configuration as that described with reference to FIG. 6. That is, the gas supply part 400 may include a source gas storage part 410 in which a source gas is stored, a reactant gas storage part 420 in which a reactant gas reacting with the source gas is stored, a purge gas storage part 430 in which a purge gas is stored, a first transfer tube 470a installed to connect the source gas storage part 410 to the first gas injection part 300a, and a second transfer tube 470b installed to connect the reactant gas storage part 420 and the purge gas storage part 430 to the second gas injection part 300b.

In addition, the gas supply part 400 may include a gas storage part for generating plasma, in which the gas supplied in a process of generating plasma inside the chamber 100 (hereinafter, referred to as plasma generating gas) is stored after the reactant gas is injected or after the secondary purging 440. Here, the gas for generating the plasma may be, for example, a hydrogen gas.

In addition, the gas supply part 400 may include a doping gas storage part 450, in which a doping gas is stored, and a mixing part 460 installed in the first transfer tube 470a to mix a plurality of types of gases.

In addition, the gas supply part 400 may include a plurality of first connection tubes 480a connecting each of the source gas storage part 410 and the doping gas storage part 450 to the first transfer tube 470a, a valve installed in each of the plurality of first connection tubes 480a, a plurality of second connection tubes 480b connecting each of the reactant gas storage 420, the purge gas storage 430, and the gas storage 440 for generating the plasma to the second transfer tube 470b, and a valve installed in each of the plurality of second connection tubes 480b.

The antenna 610 may be installed on an upper portion of the upper body 120 of the chamber 100. In this case, the antenna 610 may be provided in a spiral wound with a plurality of turns or may have a configuration including a plurality of circular coils arranged in a concentric circle shape and connected to each other. Of course, the antenna 610 is not limited to the spiral coil or the concentric circular coil, and various types of antennas having different shapes may be applied.

One end of both ends of the antenna 610 may be connected to a power supply part 620, and the other end may be connected to a ground terminal. Therefore, when power, for example, RF power is applied to the antenna 610 through the power supply part 620, a gas injected into the chamber 100 is ionized or discharged to generate plasma in the chamber 100.

The heating part 500 is a means that heats the inside and the support 200 of the chamber 100 and may be installed outside the chamber 100. More specifically, the heating part 500 may be installed so that at least a portion of a lower side outside the chamber 100 faces the support 200. The heating part 500 may be a means including a plurality of lamps, and the plurality of lamps may be installed to be arranged in a width direction of the support 200. Also, the plurality of lamps may include lamps such as halogen that emits radiant heat.

Hereinafter, a method of manufacturing the power semiconductor device in accordance with an exemplary embodiment will be described with reference to FIGS. 2 and 3. Here, the description will be made using the deposition device of FIG. 6, and a field effect transistor will be described as an example.

First, a heater 210 provided in a support 200 operates to heat the support 200. Here, the heater operates so that a temperature of the support 200 or the substrate S to be seated on the support 200 is, for example, approximately 500° C. to approximately 520° C.

Next, the substrate S, for example, a substrate S made of SiC is loaded into the chamber 100 so as to be seated on the support 200. In this case, one or more substrates S may be provided on the support 200. Thereafter, when the substrate S seated on the support 200 reaches a target process temperature, for example, approximately 500° C. to approximately 520° C., the active layer 10 is formed on the substrate S.

In this case, the active layer 10 is formed using an atomic layer deposition method. Also, the atomic layer deposition is performed in order of an injection of a source gas, an injection of a purge gas (primary purging), an injection of a reactant gas, and an injection of the purge gas (secondary purging). Here, plasma is generated inside the chamber 100 after the secondary purging. That is, the process cycle of forming the active layer 10 by the atomic layer deposition method may be a cycle of ‘the injection of the source gas-the injection of the purge gas (primary purging)-the injection of the reactant gas-the injection of the purge gas (secondary purging)-generation of plasma’. Then, the above-described process cycle is repeated a plurality of times to form the active layer 10 having a target thickness.

Hereinafter, the method for forming the active layer 10 by injecting a process gas into the chamber 100 using an injection part 300 and a gas supply part 400 will be described in more detail. In this case, the case of forming the active layer 10 made of AlGaInP will be described as an example.

First, the source gas is injected into the chamber 100. For this, each of an Al-containing gas stored in a first source gas storage part 410, a Ga-containing gas stored in a second source gas storage part 410, and an In-containing gas stored in a third source gas storage part 410 is supplied into a mixing part 460. Thus, three kinds of source gases, that is, the Al-containing gas, the Ga-containing gas, and the In-containing gas are mixed in the mixing part 460.

The mixed source gas is introduced into a diffusion space 350 in the injection part 300 through a first transfer tube 470a and a first gas supply tube 500a. Then, the mixed source gas is diffused in the diffusion space 350 and then passes through a plurality of nozzles 320, that is, a plurality of first paths 360a and is injected toward the substrate S.

When the injection of the source gas is stopped or finished, the purge gas is provided through the purge gas storage part 430 to inject the purge gas into the chamber 100 (primary purging). Here, the purge gas discharged from the purge gas storage part 430 may pass through the second connection tube 480b, the second transfer tube 470b, and the second gas supply tube 500b and then be injected downward through a second path 360b.

Next, the reactant gas, for example, a P-containing gas, is provided from the reactant gas storage part 420 and injected into the chamber 100. In this case, the reactant gas may be injected into the chamber 100 through the same path as the purge gas. That is, after passing through the second connection tube 480b, the second transfer tube 470b, and the second gas supply tube 500b, the reactant gas may be injected downward through the second path 360b. When the reactant gas is injected, a reaction between the source gas adsorbed on the substrate S and the reactant gas may occur to generate a reactant, that is, AlGaInP. Then, the reactant is accumulated or deposited on the substrate S to form a thin film made of AlGaInP on the substrate S.

When the reactant gas is injected into the chamber 100 in this manner, an RF power supply part 600 may operate to apply RF power to the first plate 310. When the RF power is applied to the first plate 310, plasma may be generated in the second path 360b in the injection part 300 and in a space between the first plate 310 and the support 200.

When the reactant gas injection is stopped, the purge gas is supplied through the purge gas storage part 430 to inject the purge gas into the chamber 100 (secondary purging). In this case, by-products of the reaction between the source gas and the reactant gas may be discharged to the outside of the chamber 100 by the secondary purging.

When the secondary purging is finished, a gas such as a hydrogen gas is provided from the gas storage part 440 for generating the plasma, and the RF power is turned on to apply the RF power to the first plate 310. Thus, the plasma using the hydrogen gas, that is, hydrogen plasma is generated in the chamber 100.

As described above, the plasma may be generated in the chamber 100 after injecting the reactant gas or the secondary purging, the active layer 10 may be formed on the substrate S even at a low temperature of approximately 600° C. or less. In addition, more specifically, the polycrystalline active layer 10 may be formed.

The process cycle performed in the order of ‘the injection of the source gas, the injection of the purge gas (primary purging), the injection of the reactant gas, the injection of the purge gas (secondary purging), and the generation of the plasma’ as described above may be repeated a plurality of times. In addition, the number of times of the process cycle to be performed may be determined according to the target thickness.

When the active layer 10 having the target thickness is formed, a portion of the active layer 10 is etched. For example, the active layer 10 having a predetermined thickness is etched in an outer area of a central area in a width or length direction of the active layer 10. For this, for example, a mask for covering closing the central area of the active layer 10 and exposing opening a remaining area is prepared, and the mask is disposed on an upper side of the active layer 10. Then, the active layer 10 exposed to the opening area is partially etched by injecting an etching gas from the upper side of the active layer 10. Here, the etching is performed so that the active layer 10 facing the opening area of the mask remains to have the target thickness. At this time, the etching gas may be used for the etching by applying at least one of SF6, Cl2, CF4, or O2 or a combination of the two gases and plasma.

Due to this etching, the active layer 10 may be provided in a form including the first layer 11 formed on a top surface of the substrate S and the second layer 12 formed on the central area of the first layer 11. Thus, the active layer 10 may be provided in a shape in which a height of an area, on which the second layer 12 is formed, is greater than that of a portion, at which only the first layer 11 is formed, that is, in a shape having a height difference.

As described above, the process of etching a portion of the active layer may be performed in a device that is separated from the deposition device illustrated in FIG. 6. In addition, the etching device may be a device connected to the deposition device in situ.

When the etching is finished, well layers 21 and 22 are formed in the first layer 11 of the active layer 10. In this case, the well layers 21 and 22 may be formed through, for example, an atomic layer deposition method and may be formed using the same deposition device as when the active layer 10 is formed.

Hereinafter, the method for forming the well layers 21 and 22 will be described, and the method of forming the well layers 21 and 22 using the deposition device illustrated in FIG. 6 will be described. In this case, a case in which the well layers 21 and 22 are formed using an n-type AlGaInP layer will be described as an example.

First, the substrate S on which the active layer 10 is formed is loaded into the chamber 100 to be seated on the support 200. Then, an area of the active layer 10 facing the second layer 12 is closed, and a remaining opened mask is disposed above the active layer 10.

Next, the source gas is injected into the chamber 100. For this, each of an Al-containing gas stored in a first source gas storage part 410, a Ga-containing gas stored in a second source gas storage part 410, an In-containing gas stored in a third source gas storage part 410, and an Si-containing gas stored in a doping gas storage part 450 is supplied into a mixing part 460. Thus, the Al-containing gas, the Ga-containing gas, the In-containing gas, and the Si-containing gas are mixed in the mixing part 460. The mixed gases are injected toward the substrate S by passing through the first transfer tube 470a, the first gas supply tube 500a and the first path 360a of the injection part 300.

Thereafter, the purge gas is supplied from the purge gas storage part 430, and the purge gas is injected into the chamber 100 through the second path 360b of the injection part 300 (primary purging).

Next, a reactant gas, for example, a P-containing gas is provided from the reactant gas storage part 420 and injected into the chamber 100 through the second path 360b of the injection part 300. Here, RF power may be applied to the first plate 310 to generate plasma.

When the reactant gas is injected, a reaction between the source gas adsorbed on the substrate S and the reactant gas may occur to generate a reactant, that is, AlGaInP. Here, since the source gas and the doping gas are mixed and injected, the reactant becomes AlGaInP doped with Si. Thus, the well layers 21 and 122 provided as an n-type AlGaInP layer may be formed in the first layer 11 of the active layer 10.

When the reactant gas injection is finished, the purge gas is supplied from the purge gas storage part 430 to inject the purge gas into the chamber 100 (secondary purging).

When the secondary purge is finished, the process of generating plasma in the chamber 100 may be added. That is, a gas, for example, the hydrogen gas is supplied from the gas storage part 440 for generating the plasma, the hydrogen gas is injected into the chamber 100, and the RF power is applied to the first plate 310. Thus, the plasma using the hydrogen gas, that is, hydrogen plasma is generated in the chamber 100.

Thereafter, the process cycle performed in the order of ‘the injection of the source gas (mixing of the source gas+the doping gas), the injection of the purge gas (primary purging), the injection of the reactant gas, the injection of the purge gas (secondary purging), and the generation of the plasma’ is repeated a plurality of times to form the well layers 21 and 22, each of which has a target thickness. Here, as illustrated in FIG. 2, the well layers 21 and 22 may be provided to surround the second layer 12 on the first layer 11 of the active layer 10.

In the above, in the forming of the well layers 21 and 22, it has been described that the plasma is generated after the secondary purging. However, an exemplary embodiment is not limited thereto, and the process of generating the plasma after the secondary purging may be omitted.

When the well layers 21 and 22 are formed, a gate insulating layer 30 is formed on the active layer 10 and the well layers 21 and 22. Here, the gate insulating layer 30 may be made of, for example, Al₂O₃ and may be formed through any one of a chemical vapor deposition method, an organometallic chemical vapor deposition method, and an atomic layer deposition method.

Thereafter, a portion of the gate insulating layer 30 is etched. For example, the gate insulating layer 30 formed on an edge of each of the well layers 21 and 22 is etched. Thus, as illustrated in FIG. 1, the gate insulating layer 30 may be provided on the second layer 12 of the active layer 10, and in this case, the gate insulating layer 30 may have a length greater than that of the second layer 12.

Next, a source electrode 41 is formed at one side of the gate insulating layer 30, and a drain electrode 42 is formed at the other side of each of the well layers 21 and 22. In this case, the source and drain electrodes 41 and 42 may be formed using at least one material of Ti or Au and may be formed through, for example, sputtering deposition.

Then, the gate electrode 50 is formed on the gate insulating layer 30. Here, the gate electrode 50 may be prepared using the same material and the same method as the source and drain electrodes 41 and 42. For example, the gate electrode 50 may be made of at least one of Ti or Au, and may be formed through the sputtering deposition method.

As described above, in accordance with the method for manufacturing the power semiconductor device in accordance with the exemplary embodiment, the active layer 10 may be formed at the low temperature. Therefore, the substrate S or the thin film formed on the substrate may be prevented from being damaged by the high-temperature heat. In addition, the power or time required for heating the substrate S to form the active layer 10 may be saved, and the overall process time may be shortened.

In addition, the active layer 10 may be crystallized to be formed. That is, the crystallized active layer 10 may be formed while forming the active layer at the low temperature.

### INDUSTRIAL APPLICABILITY

In accordance with the exemplary embodiments, the active layer may be formed at the low temperature. Thus, the substrate or the thin film formed on the substrate may be prevented from being damaged by the high-temperature heat. In addition, the power or time required for heating the substrate to form the active layer may be saved, and the overall process time may be shortened.

In addition, the active layer may be crystallized to be formed. That is, the crystallized active layer may be formed while forming the active layer at the low temperature.

1. A method for manufacturing a power semiconductor device, which comprises forming an active layer on an SiC substrate,
wherein the forming of the active layer comprises:
injecting a source gas onto the SiC substrate;
performing a primary purging of injecting a purge gas after stopping the injecting of the source gas;
injecting a reactant gas after stopping the primary purging; and
performing a secondary purging of injecting the purging gas after stopping the injecting of the reactant gas.

2. The method of claim 1, wherein the source gas comprises one or two or more of Ga, In, Zn, and Si.

3. The method of claim 2, wherein the reactant gas comprises one or two or more of As, P, O, and C.

4. The method of claim 3, wherein the forming of the active layer comprises repeatedly performing one process cycle, in which the injecting of the source gas, performing of the primary purging, the injecting of the reactant gas, and the performing of the secondary purging are sequentially performed.

5. The method of claim 1, wherein the forming of the active layer comprises generating a plasma after the injecting of the reactant gas.

6. The method of claim 5, wherein the generating of the plasma after the injecting of the reactant gas is performed after the performing of the secondary purging, and
the forming of the active layer comprises repeatedly performing one process cycle, in which the injecting of the source gas, the performing of the primary purging, the injecting of the reactant gas, the performing of the secondary purging, and the generating of the plasma are sequentially performed.

7. The method of claim 1, wherein the forming of the active layer comprises generating a plasma between the injecting of the source gas and the injecting of the reactant gas.

8. The method of claim 5, wherein the generating of the plasma comprises injecting a hydrogen gas.

9. The method of claim 1, wherein injecting the reactant gas comprise generating a plasma by discharging the reactant gas.

10. The method of claim 9, wherein the forming of the active layer comprises generating a plasma after the injecting of the reactant gas.

11. The method of claim 1, further comprising forming a well region in the active layer after the forming of the active layer,
wherein the forming of the well region comprises:
exposing a partial area of the active layer in which the well region is formed;
etching the exposed partial area of the active layer; and
sequentially performing the injecting of the source gas, the injecting of the purge gas, the injecting of the reactant gas, and the injecting of the purge gas to form the well region in the exposed area of the active layer.

12. The method of claim 11, wherein at least one of the forming of the active layer and the forming of the well region comprises injecting a doping gas,
wherein the doping gas is injected after the doping gas is mixed with the source gas and is injected or after the source gas is injected.

13. The method of claim 12, wherein the doping gas comprises one of Mg, Si, In, Al, and Zn.

14. The method of claim 11, further comprising:
forming a gate insulating layer on the active layer;
forming a source electrode and a drain electrode on the well region so that the source electrode and the drain electrode are spaced apart from each other in a horizontal direction; and
forming a gate electrode on the gate insulating layer.

15. The method of claim 9, wherein the forming of the active layer comprises generating a plasma between the injecting of the source gas and the injecting of the reactant gas.
